(19) United States
(12) Patent Application Publication
(10) Pub. No.: US 2012/0152355 A1
(43) Pub. Date: Jun. 21, 2012

(54) ORGANIC SOLAR CELL

(75) Inventors: Jau-Min Ding, Taipei City (TW); Ching Ting, Hsinchu County (TW); Shu-Hua Chan, Miaoli County (TW)

(73) Assignee: INDUSTRIAL TECHNOLOGY RESEARCH INSTITUTE, Hsinchu (TW)

(21) Appl. No.: 12/981,478

(22) Filed: Dec. 30, 2010

(30) Foreign Application Priority Data
Dec. 15, 2010 (TW) 99144056

(51) Int. Cl. H01L 51/46

(52) U.S. Cl. 136/263

(57) ABSTRACT

An organic solar cell is provided. The organic solar cell includes a substrate, a first electrode, a second electrode and a photoelectric conversion layer. The first electrode is disposed on the substrate. The second electrode is disposed on the first electrode. The photoelectric conversion layer is disposed between the first electrode and the second electrode. The photoelectric conversion layer contains a fully conjugated block copolymer including a block having an electron withdrawing group and a block having an electron donating group.

### TECHNICAL FIELD

The disclosure relates to a photoelectric conversion device, and more particularly to an organic solar cell.

### BACKGROUND

Solar energy is a clean, pollution-free, and inexhaustible energy, and has been the focus of being an alternative energy resource with the potential of solving the problem of shortage of fossil energy supply as well as the pollution caused by using of fossil fuel. Therefore, solar cells, which are electronic devices designed to convert the solar energy into electricity, have become a very important research subject

Organic solar cells which include two electrodes and a photoelectric conversion layer located between the two electrodes, are attracting intense interest due to the ability to produce them using high-throughput manufacturing techniques, In particular, the bulk heterojunction solar cell, which has a photoelectric conversion layer comprised of blend of an electron donor (e.g. poly(3-hexylthiophene)-P3HT) and an electron acceptor (e.g. [6,6]-phenyl-C61 butyric acid methyl ester-PCBM), has been one of the most studied system in this field based on the possibility of fabricating from solution at low temperature using high speed printing and coating techniques.

However, an annealing step must be performed in the current fabricating process for a bulk heterojunction device, to optimize the morphology of the photoelectric conversion layer and thus complicates the fabricating process. In addition, a blend composed of electron acceptor material and electron donor material is difficult to achieve a desired uniformity, thus resulting in a poor performance of the organic solar cell.

Furthermore, a carbon derivative (e.g. PCBM) is usually used as the electron acceptor material. However, the manufacturing cost of the organic solar cell is increased accordingly due to the high cost of the PCBM.

### SUMMARY

Embodiments disclosed herein may provide an organic solar cell. The organic solar cell may include a substrate, a first electrode, a second electrode, and a photoelectric conversion layer. The first electrode is disposed on the substrate. The second electrode is disposed on the first electrode. The photoelectric conversion layer is disposed between the first electrode and the second electrode. The photoelectric conversion layer contains a fully conjugated block copolymer, and the fully conjugated block copolymer includes a block having an electron withdrawing group and a block having an electron donating group.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional diagram of an organic solar cell according to an embodiment of the disclosure;

FIG. 2 is an atomic force microscopy (AFM) phase diagram of a photoelectric conversion layer only containing P3HT;

FIG. 3 is an AFM phase diagram of a photoelectric conversion layer containing 30% of C₆₀-BCP and P3HT; and

FIG. 4 is a diagram illustrating a relation between light absorption efficiency and a content of a fully conjugated block copolymer.

### DETAILED DESCRIPTION OF DISCLOSED EMBODIMENTS

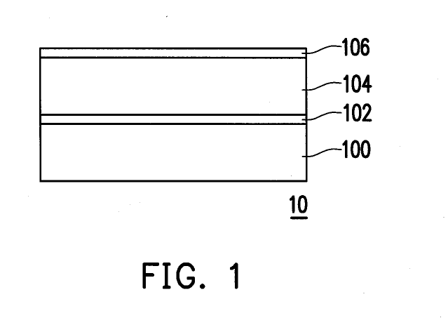

FIG. 1 is a schematic cross-sectional diagram of an organic solar cell according to an embodiment of the disclosure. Referring to FIG. 1, an organic solar cell 10 includes a substrate 100, a first electrode 102, a second electrode 106, and a photoelectric conversion layer 104. The substrate 100 is, for example, a transparent substrate. The material of the substrate 100 may be glass, transparent resin, or other suitable materials. The transparent resin is, for example, polyethylene terephthalate (PET), polyethylene naphthalate (PEN), polycarbonate (PC), polyethersulfone (PES), and polyimide (PI). The first electrode 102 is disposed on the substrate 100. The material of the first electrode 102 may be a transparent conductive oxide, a metal, or a conductive macromolecule. The transparent conductive oxide is, for example, indium tin oxide (ITO), Al doped ZnO (AZO), and indium zinc oxide (IZO). The metal may be gold, silver, copper, aluminum, or titanium. The conductive macromolecule may be poly(3,4-ethylenedioxythiophene) (PEDOT). The second electrode 106 is disposed on the first electrode 102. Similarly, the material of the second electrode 106 may be a transparent conductive oxide, a metal, or a conductive macromolecule. The photoelectric conversion layer 104 is disposed between the first electrode 102 and the second electrode 106. The photoelectric conversion layer 104 contains a fully conjugated block copolymer, and the fully conjugated block copolymer includes a block having an electron withdrawing group and a block having an electron donating group. In this embodiment, the organic solar cell 10 may further include a hole transport layer (HTL) and an electron transport layer (ETL) (not shown). The HTL includes a metal oxide or a conjugated polymer. The metal oxide may be, for example, vanadium oxide and copper oxide. The conjugated polymer may include poly(3,4-ethylenedioxythiophene) (PEDOT). The ETL includes a metal oxide or a metal halide. The metal oxide may be, for example, zinc oxide and titanium oxide. The metal halide may be, for example, lithium fluoride.

In the embodiment of the disclosure, the fully conjugated block copolymer may be represented by Formula (1) or Formula (2):

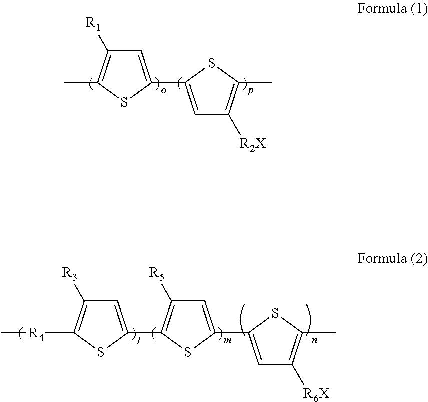

in which R₁, R₃, and R₅ are independently hydrogen, alkyl, hydroxyl, halogen, cyano (—CN), nitro group (—NO₂), amino, substituted or unsubstituted aryl, or substituted or unsubstituted heteroaryl, and R₃ and R₄ may be combined into a ring, in which the ring may be carbazolyl, dithiophenyl, fluorenyl, thiadiazolyl, quinoxalinyl, dibenzosilolyl, benzodithiophenyl, and the like; R₂ and R₆ are independently a linear or branched C₁ to C₁₂ hydrocarbon linking group, and may include ester group, amino, alkyl, or alkoxy; X is a fullerene derivative; o is an integer between 3 to 5000; p is an integer between 2 to 1000; 1 is an integer between 0 to 100; m is an integer between 3 to 5000; and n is an integer between 2 to 1000.

In addition, R₃ and R₄ in the fully conjugated block copolymer of Formula (2) may also be combined into a ring, and the fully conjugated block copolymer may be represented by Formula (3):

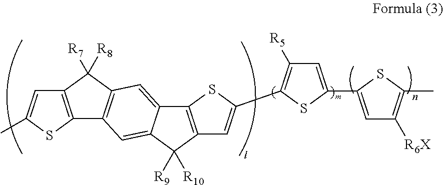

in which R₇, R₈, R₉, and R₁₀ may be hydrogen, alkyl, hydroxyl, halogen, cyano (—CN), nitro group (—NO₂), amino, substituted or unsubstituted aryl, or substituted or unsubstituted heteroaryl.

Since the fully conjugated block copolymer includes a block having an electron withdrawing group and a block having an electron donating group, the fully conjugated block copolymer may be provided with functions of an electron acceptor material and an electron donor material at the same time. Thus, in an embodiment, the fully conjugated block copolymer may be used as the material of the photoelectric conversion layer 104, that is, the photoelectric conversion layer 104 only contains the fully conjugated block copolymer.

Alternatively, in another embodiment, the fully conjugated block copolymer may replace a common electron donor material, that is, the photoelectric conversion layer 104 contains the fully conjugated block copolymer and an electron acceptor material. The electron acceptor material is, for example, fullerenes, oxadiazoles, carbon nanorods, inorganic nanoparticles, inorganic nanorods, or combinations thereof.

Alternatively, in another embodiment, the fully conjugated block copolymer may replace a common electron acceptor material, that is, the photoelectric conversion layer 104 contains the fully conjugated block copolymer and an electron donor material. The electron donor material is, for example, discotic liquid crystals, polythiophenes, polyphenylenes, polysilanes, or polythienylvinylenes.

Alternatively, in another embodiment, the photoelectric conversion layer 104 may also contain the fully conjugated block copolymer, an electron acceptor material, and an electron donor material at the same time. At this time, the fully conjugated block copolymer may be used as a blending agent, to improve the compatibility of the electron acceptor material and the electron donor material.

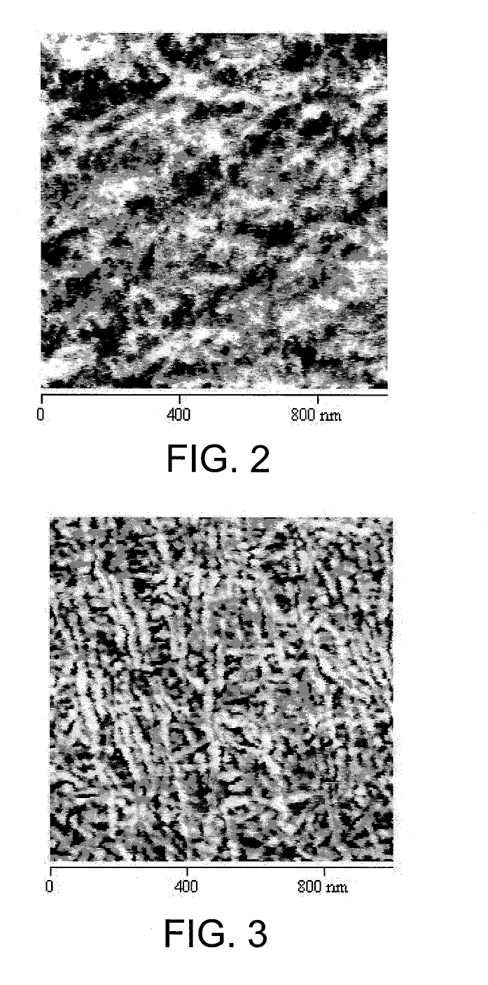

In the above embodiments, the photoelectric conversion layer 104 contains the fully conjugated block copolymer, which may increase the crystalline arrangement of the electron acceptor material or the electron donor material, and thus the light absorption efficiency of the photoelectric conversion layer 104 is increased. As shown in FIG. 2 and FIG. 3, compared with a photoelectric conversion layer (FIG. 2) only containing an electron donor material, for example, poly(3-hexylthiophene) (P3HT), a photoelectric conversion layer (FIG. 3) containing 30% of the fully conjugated block copolymer (for example, C₆₀-BCP, which is described below in details) and P3HT may be formed into a fibrous form, which is beneficial to improving the light absorption efficiency of the photoelectric conversion layer.

It should be particularly noted that, since the photoelectric conversion layer containing the fully conjugated block copolymer is fabricated by adopting a solution process, the annealing process may not need to be performed additionally, and thus the process is simplified, thereby achieving the purpose of increasing the capacity.

[Preparation of Fully Conjugated Block Copolymer]

A fully conjugated block copolymer containing C₆₀ (C₆₀-BCP) is prepared, and in this embodiment, the synthesis of P3C₆₀HT-b-P3HT is taken as an example, and the synthesis route is as follows.

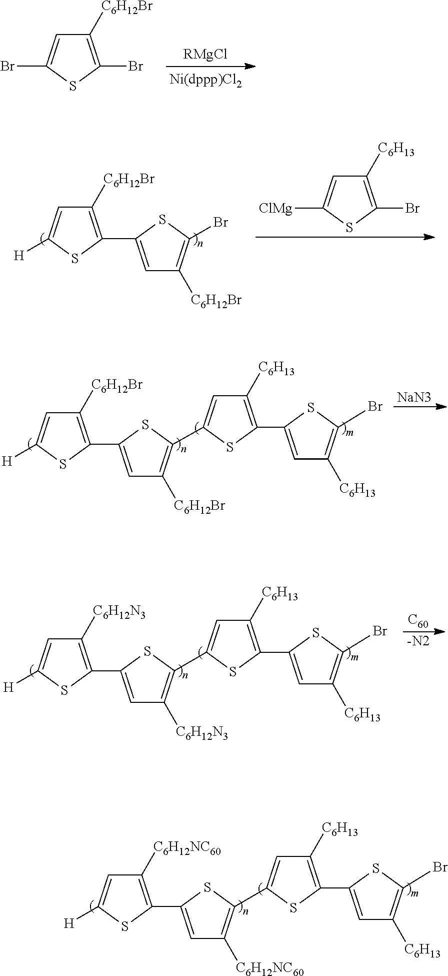

Synthesis of P3BrHT-b-P3HT

In a nitrogen environment, 3BrHT (2,5-dibromo-6-bromo-3-hexylthiophene) (1 eq.) was added into anhydrous tetrahydrofuran (THF) at 0° C. with stirring, then isopropyl magnesium chloride (1.1 e.g.) was added, and the temperature was warmed back to the room temperature (Solution 1). Solution 1 was heated up to 50° C. and Ni(dppe)Cl₂ catalyst (0.02 e.g.) was added for reaction, and 0.5 ml solution was taken out to measure the molecular weight of the polymer (P3BrHT, Mw=3131). 2BrHT (2,5-dibromo-3-hexylthiophene) (1 eq.) was added into THF at 0° C. with stirring, then isopropyl magnesium chloride (1.1 e.q.) was added, and the temperature was still controlled at 0° C. After the mixture was warmed back to the room temperature, the mixture was added to the solution 1, and the resulting solution was stirred at 50° C. for continuing reaction. Afterwards, the reaction was quenched by adding HCl solution and using methanol to drop into the solution for precipitation, to obtain a block polymer P3(BrHT)_{0.15}-b-P3HT_{0.85} (the subscripts are the molar percentages) with a molecular weight of 11422 (g/mol).

Synthesis of P3N₃HT-b-P3HT

0.5 g P3BrHT-b-P3HT (1 e.q.) was dissolved in 100 ml dimethyl fumarate (DMF), and the solution was heated to 120° C., and then 1.3 g NaN₃ (10 e.q.) was added for reaction. After the solution was cooled down to the room temperature, a large quantity of methanol was added for precipitation, and the precipitate was purified with Soxhlet extraction, to obtain a block polymer having a N₃ functional group, P3N₃HT-b-P3HT.

¹H NMR (CDCl₃): 6.95 (s, 1H), 3.25 (t, 2H), 2.80 (t, 2H), 1.51 (m, 8H), 0.9 (t, 3H)

Synthesis of P3C₆₀HT-b-P3HT

0.5 g P3N₃HT-b-P3HT was dissolved in 50 ml chlorobenzene and was deoxygenated. Then, 2 eq C₆₀ was added, and the solution was heated to 100° C. for reaction. After the solution was cooled down to the room temperature, a large quantity of methanol was added for precipitation, and the precipitate was purified with Soxhlet extraction, to obtain a block polymer having a C₆₀ functional group.

¹H NMR (CDCl₃): 6.95 (s, 1H), 2.80 (t, 2H), 1.51 (m, 8H), 0.9 (t, 3H)

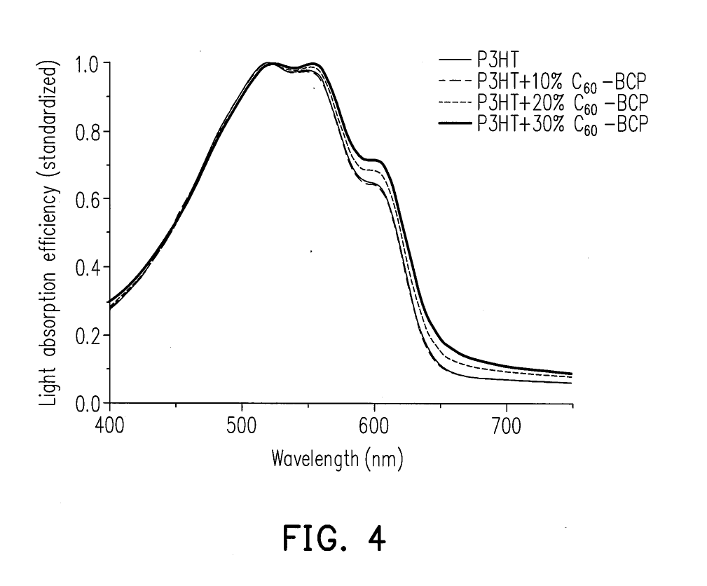

FIG. 4 is a diagram illustrating a relation between light absorption efficiency and a content of the fully conjugated block copolymer. It can be seen from FIG. 4, when the photoelectric conversion layer only contains an electron donor material (e.g. P3HT), the light absorption efficiency of the membrane layer was poor. With the increase of the content of the fully conjugated block copolymer (C₆₀-BCP), the light absorption efficiency of the photoelectric conversion layer gets good.

Fabrication of Organic Solar Cell Device

The organic solar cell device prepared according to an embodiment includes: a first electrode, made of ITO; a hole transport layer (HTL), made of poly(3,4-ethylenedioxythiophene):poly(styrene-sulfonate) (PEDOT:PSS), and formed on the first electrode; a photoelectric conversion layer, containing a fully conjugated block copolymer, and formed on the HTL; and a second electrode, made of Ca/Al. The photoelectric conversion layer may be, for example, formed by mixing the fully conjugated block copolymer and [6,6]-phenyl-C-butyric acid methyl ester (PCBM) at a ratio of 1:1, in which the C in the PCBM may be a derivative of C₆₁ or C₇₁. The efficiency was measured at an intensity of solar luminance of AM 1.5.

The preparation in this embodiment includes the following steps.
1. A solution of the photoelectric conversion layer (the fully conjugated block copolymer/PCBM=1:3, 10 mg/ml) was formulated, and stirred overnight.
2. An ITO glass was cleared with ultrasonic vibration by using acetone and isopropanol respectively, dried by blowing with nitrogen, and placed on a heating plate for baking.
3. The ITO glass was placed under an oxygen plasma for 5 min.
4. The hole transport layer was spin-coated at 3000 rpm/30 sec, and then the ITO glass was placed in a glove box and heated and baked at 150° C.
5. The ITO glass was placed on a heating plate at 140° C. for annealing, and then stood still for cooling.
6. The photoelectric conversion layer (the fully conjugated block copolymer/PCBM=1:1, w/w) was spin-coated at 450 rpm/60 sec in the glove box.
7. A mask was placed on the ITO glass, and a Ca/Al electrode was evaporated.
8. The device was packaged, and I-V measurement was performed.

The efficacy of the disclosure is described below with embodiments and comparative examples.

### Embodiment 1

The photoelectric conversion layer contains C₆₀-BCP and an electron acceptor material (PCBM).

### Embodiment 2

The photoelectric conversion layer contains C₆₀-BCP, an electron acceptor material (PCBM), and an electron donor material (P3HT) at the same time.

### Comparative Example 1

The photoelectric conversion layer contains a common electron acceptor material (PCBM) and a common electron donor material (P3HT).

TABLE 1

| | | | Short- | Open- | | Photoelectric |
|---|---|---|---|---|---|---|
| | C₆₀- | | circuit | circuit | | conversion |
| P3HT | BCP | PCBM | current | voltage | Filling | efficiency |
| (mg/ml) | (mg/ml) | (mg/ml) | (mA/cm²) | (V) | factor | (%) |
| | 15 | 15 | 2.54 | 0.61 | 0.45 | 0.7 |
| 13.5 | 1.5 | 15 | 10.5 | 0.606 | 0.672 | 4.27 |
| 15 | | 15 | 4.31 | 0.647 | 0.456 | 1.27 |

Table 1 shows the short-circuit current density (J_{sc}), the filling factor (FF), and the device efficacy (the photoelectric conversion efficiency, PCE) of Embodiments 1-2 and Comparative Example 1.

It should be noted that, in the case that the photoelectric conversion layer contains the fully conjugated block copolymer, the electron acceptor material, and the electron donor material at the same time, cheap C₆₀ may be used to replace the expensive common electron acceptor material PCBM, so as to reduce the cost.

### Comparative Example 2

The photoelectric conversion layer contains a common electron acceptor material (C₆₀) and a common electron donor material (P3HT).

### Embodiment 3

The photoelectric conversion layer contains C₆₀-BCP, an electron acceptor material (C₆₀), and an electron donor material (P3HT) at the same time.

Table 2 shows the short-circuit current density, the filling factor, and the device efficacy when the photoelectric conversion layer contains a blending agent C₆₀-BCP at different ratios.

TABLE 2

| P3HT:C₆₀ = 1:0.5 | J_{sc} (mA/cm²) | FF | PCE (%) |
|---|---|---|---|
| 0% C₆₀-BCP | 1.9 | 0.51 | 0.48 |
| 10% C₆₀-BCP | 9.2 | 0.56 | 2.42 |
| 20% C₆₀-BCP | 9.0 | 0.58 | 2.56 |
| 30% C₆₀-BCP | 8.4 | 0.51 | 2.10 |

It can be known from Table 2, in the case that the photoelectric conversion layer contains C₆₀-BCP, cheap C₆₀ may be used to replace the expensive electron acceptor material PCBM. Compared with the Comparative Example 2 (the photoelectric conversion layer contains C₆₀ and P3HT at the same time), the photoelectric conversion layer of Embodiment 3 is better in aspects of the short-circuit current density, the filling factor, and the device efficacy.

Since the photoelectric conversion layer according to an embodiment of the disclosure contains the fully conjugated block copolymer including a block having an electron withdrawing group and a block having an electron donating group, the photoelectric conversion layer according to the embodiment of the disclosure is better in aspects of the short-circuit current density, the filling factor, and the device efficacy.

In addition, when the photoelectric conversion layer contains the fully conjugated block copolymer, cheap C₆₀ may be used to replace the expensive common electron acceptor material, so as to reduce the cost.

Furthermore, since the photoelectric conversion layer containing the fully conjugated block copolymer may be fabricated by adopting a solution process, the subsequent processing (for example, the annealing process) may be omitted, thus shorting the process time and increasing the capacity.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

1. An organic solar cell, comprising:
a substrate;
a first electrode, disposed on the substrate;
a second electrode, disposed on the first electrode; and
a photoelectric conversion layer, disposed between the first electrode and the second electrode, and containing a fully conjugated block copolymer, wherein the fully conjugated block copolymer comprises a block having an electron withdrawing group and a block having an electron donating group.

2. The organic solar cell according to claim 1, wherein the fully conjugated block copolymer is represented by Formula (1): 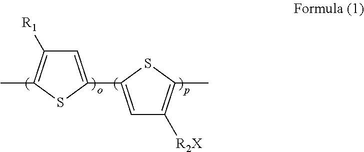
wherein R1 is hydrogen, alkyl, hydroxyl, halogen, cyano (—CN), nitro group (—NO₂), amino, substituted or unsubstituted aryl, or substituted or unsubstituted heteroaryl; R2 is a linear or branched C₁ to C₁₂ hydrocarbon linking group, and comprises ester group, amino, alkyl, or alkoxy; X is a fullerene derivative; o is an integer between 3 to 5000; and p is an integer between 2 to 1000.

3. The organic solar cell according to claim 1, wherein the fully conjugated block copolymer is represented by Formula (2): 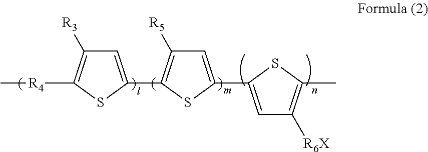
wherein R3 and R5 are independently hydrogen, alkyl, hydroxyl, halogen, cyano (—CN), nitro group (—NO₂), amino, substituted or unsubstituted aryl, or substituted or unsubstituted heteroaryl, and R3 and R4 are capable of being combined into a ring; R6 is a linear or branched C₁ to C₁₂ hydrocarbon linking group, and comprises ester group, amino, alkyl, or alkoxy; X is a fullerene derivative; 1 is an integer between 0 to 100; m is an integer between 3 to 5000; and n is an integer between 2 to 1000.

4. The organic solar cell according to claim 3, wherein R3 and R4 are combined into a ring, and the ring comprises carbazolyl, dithiophenyl, fluorenyl, thiadiazolyl, quinoxalinyl, dibenzosilolyl, or benzodithiophenyl.

5. The organic solar cell according to claim 3, wherein R3 and R4 are combined into a ring and the resulted fully conjugated block copolymer is represented by Formula (3): 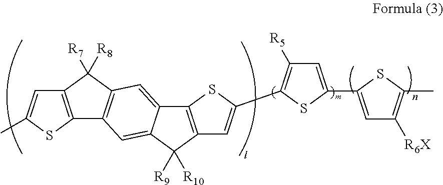
wherein R7, R8, R9, and R10 are hydrogen, alkyl, hydroxyl, halogen, cyano (—CN), nitro group (—NO₂), amino, substituted or unsubstituted aryl, or substituted or unsubstituted heteroaryl.

6. The organic solar cell according to claim 1, wherein the photoelectric conversion layer further comprises an electron acceptor material.

7. The organic solar cell according to claim 6, wherein the electron acceptor material comprises fullerenes, oxadiazoles, carbon nanorods, inorganic nanoparticles, inorganic nanorods, or combinations thereof.

8. The organic solar cell according to claim 1, wherein the photoelectric conversion layer further comprises an electron donor material.

9. The organic solar cell according to claim 8, wherein the electron donor material comprises discotic liquid crystals, polythiophenes, polyphenylenes, polysilanes, or polythienylvinylenes.

10. The organic solar cell according to claim 1, wherein the photoelectric conversion layer further comprises an electron acceptor material and an electron donor material.
